(19) United States
(12) Patent Application Publication
(10) Pub. No.: US 2006/0076641 A1
(43) Pub. Date: Apr. 13, 2006

(54) Methods of fabricating phase changeable semiconductor memory devices including multi-plug conductive structures and related devices

(75) Inventors: Byeong-Ok Cho, Seoul (KR); Sang-Don Nam, Seoul (KR); Suk-Hun Choi, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/209,938

(22) Filed: Aug. 23, 2005

(30) Foreign Application Priority Data
Aug. 23, 2004 (KR) 10-2004-66532

(51) Int. Cl. H01L 29/40; H01L 21/44

(52) U.S. Cl. 257/528; 438/675; 438/652; 438/381; 257/750; 257/774

(57) ABSTRACT

In fabricating a phase changeable memory device, an insulating layer with an opening extending therethrough is formed on a substrate. A conductive structure is formed in the opening. The conductive structure includes a first conductive plug on opposing sidewalls of the opening and a surface therebetween and a second plug on the first conductive plug. The first conductive plug is between the second plug and the sidewalls of the opening and between the second plug and the surface therebetween. A lower electrode is formed on the first conductive plug, on the second plug, and on the insulating layer. The lower electrode extends outside the opening in the insulating layer. A phase changeable material layer is formed on the lower electrode, and an upper electrode is formed on the phase changeable material layer opposite the lower electrode.

### CROSS REFERENCE TO RELATED APPLICATION

This application claims priority under 35 USC § 119 from Korean Patent Application No. 2004-66532 filed on Aug. 23, 2004, the disclosure of which is hereby incorporated by reference herein in its entirety.

### FIELD OF THE INVENTION

The present invention relates to semiconductor memory devices, and, more particularly, to phase changeable semiconductor memory devices and methods of fabricating the same.

### BACKGROUND OF THE INVENTION

Semiconductor memory devices such as dynamic random access memory (DRAM) devices, static random access memory (SRAM) devices and flash memory devices are used in various electronic devices. These semiconductor memory devices are generally classified as volatile semiconductor devices and nonvolatile semiconductor memory devices. Nonvolatile semiconductor memory devices, for example, flash memory devices, may be used in portable electronic devices such as digital cameras and cellular phones.

However, flash memory devices may require a relatively long time to write data and/or to read stored data. Thus, semiconductor memory devices such as ferroelectric random access memory (FRAM) devices, magnetic random access memory (MRAM) devices and phase changeable random access memory (PRAM) devices have been developed.

A PRAM device may include a phase changeable material. The crystal structure of the phase changeable material may be changed from a crystalline phase to an amorphous phase (and/or vice versa) when heat is applied to the phase changeable material. The phase changeable material may include a chalcogenide such as germanium-stibium-tellurium (Ge—Sb—Te; also referred to herein as GST).

The heat required to convert the crystal structure of the phase changeable material may be provided by a applying a current to the phase changeable material from an electrode. The phase changeable material may have different resistances in accordance with its physical state, and as such, data can be stored in the phase changeable material based on the different resistances. For example, the phase changeable material may have a relatively greater resistance when the phase changeable material is in the amorphous phase. On the other hand, when the phase changeable material is in the crystalline phase, the phase changeable material may have a relatively lower resistance. As such, two distinct logical states corresponding to the physical state of the phase changeable material may be provided.

Examples of PRAM devices are disclosed in U.S. Pat. No. 5,869,843 to Harshfield, U.S. Pat. No. 6,579,760 to Lung, and U.S. Pat. No. 6,236,059 to Wolstenholme. The disclosures of each of these patents are hereby incorporated by reference herein in their entirety.

FIG. 1 is a cross sectional view illustrating a conventional phase changeable semiconductor memory device.

Referring now to FIG. 1, a conventional phase changeable semiconductor memory device includes a semiconductor substrate 10 having a contact region, an insulation layer 11, a pad 14, an insulation layer 20, a metal wiring/conductive layer 30, a lower electrode 40, an insulation layer 34, a phase changeable material pattern 44, an upper electrode 48, and an insulation layer 52.

The insulation layer 11 is formed on the substrate 10. The pad 14 is formed extending through the insulation layer 11 to provide electrical contact with the contact region. The metal wiring 30 is formed on the pad 14 and the insulation layer 11 extending through the insulation layer 20.

The lower electrode 40 is formed on the metal wiring 30. A spacer 33 is formed on opposing sidewalls of the lower electrode 40. The lower electrode 40 and the spacer 33 extend through the second insulation pattern 34.

The phase changeable material layer 44 is formed on the lower electrode 40 and the insulation layer 34. The upper electrode 48 and the insulation layer 52 are sequentially formed on the phase changeable material layer 44.

In the phase changeable semiconductor memory device described above, the metal wiring 30 is formed on the pad 14 to fill an opening extending through the insulation layer 20 and exposing the pad 14. More particularly, after a metal layer is formed on the pad 14 and the insulation layer 20 to fill the opening, the metal layer is partially removed, for example, by a chemical-mechanical polishing (CMP) process, until the insulation layer 20 is exposed. Thus, the metal wiring 30 is formed in the opening. However, during formation of the metal wiring 30, a void or seam 60 may be formed in the metal wiring 30 (as shown in FIG. 1) when the metal layer is formed to fill the opening, for example, by a chemical vapor deposition (CVD) process. When such a void 60 is formed in the metal wiring 30, an interface resistance between the metal wiring 30 and the lower electrode 40 may be considerably increased. In addition, particles from the CMP process may remain on the metal wiring 30 to further increase the interface resistance between the metal wiring 30 and the lower electrode 40. Thus, a current provided to convert the crystalline structure of the phase changeable material layer 44 may be reduced between the metal wiring 30 and the lower electrode 40. As such, electrical failure of the phase changeable semiconductor memory device may result.

### SUMMARY OF THE INVENTION

According to some embodiments of the present invention, in a method of fabricating a phase changeable memory device, a first insulating layer may be formed on a substrate. The first insulating layer may have a first opening extending therethrough. A first conductive plug may be formed in the first opening on opposing sidewalls thereof and on a surface therebetween. A second plug may be formed on the first conductive plug in the first opening. The first conductive plug may be between the second plug and the sidewalls of the first opening, and between the second plug and the surface therebetween. A first lower electrode may be formed on the first conductive plug, on the second plug, and on portions of the first insulating layer outside the first opening therein. A phase changeable material layer may be formed on the first lower electrode, and an upper electrode may be formed on the phase changeable material layer opposite the first lower electrode.

In some embodiments, a second insulating layer may be formed on the first lower electrode. The second insulating layer may have a second opening extending therethrough exposing at least a portion of the first lower electrode. The phase changeable material layer may be formed on the second insulating layer, and may extend through the second opening therein to electrically contact the exposed portion of the first lower electrode.

In other embodiments, a second lower electrode may be formed on at least a portion of the first lower electrode, and may electrically connect the first lower electrode and the phase changeable material layer. For example, to form the second lower electrode, a second insulating layer having a second opening extending therethrough may be formed on the first lower electrode, and a spacer may be formed on opposing sidewalls of the second opening. The second lower electrode may be formed in the second opening adjacent the spacer. A surface area of the second lower electrode may be less than that of the first lower electrode and/or the phase changeable material layer.

In some embodiments, the first lower electrode and/or the second lower electrode may include titanium nitride, tantalum nitride, molybdenum nitride, titanium silicon nitride, titanium aluminum nitride, titanium boron nitride, zirconium nitride, tungsten silicon nitride, tungsten boron nitride, zirconium aluminum nitride, molybdenum silicon nitride, molybdenum aluminum nitride, tantalum silicon nitride, titanium aluminum oxynitride, tungsten oxynitride, titanium oxynitride, tungsten, molybdenum, aluminum, titanium, zirconium, tantalum, copper, tungsten silicide, cobalt silicide, titanium silicide, and/or tantalum silicide.

In other embodiments, the first lower electrode and/or the upper electrode may include a conductive material containing nitrogen, a metal, and/or a metal silicide.

In some embodiments, the second plug may be a second conductive plug. The second conductive plug may be formed of a different material than the first conductive plug. For example, the second conductive plug may include tungsten, aluminum, titanium, tantalum, titanium nitride, tungsten nitride, aluminum nitride, and/or titanium aluminum nitride. In other embodiments, the first conductive plug, the second plug, the first lower electrode, and/or the upper electrode may be formed of a same material.

In some embodiments, the second plug may be a second insulating plug. For example, the second insulating plug may include tetraethylorthosilicate, undoped silicate glass, spin on glass, high density plasma-chemical vapor deposition oxide, silicon nitride, and/or silicon oxynitride. Also, the second insulating plug and the first insulating layer may be formed of a same material.

In other embodiments, in forming the first conductive plug and the second plug, a first conductive layer may be formed on the first insulating layer and in the first opening on sidewalls thereof and on a surface therebetween. For example, the first conductive layer may be formed to a thickness of less than about half of a width of the first opening in the first insulating layer. A second layer may be formed on the first conductive layer. Portions of the first conductive layer and the second layer that are on the first insulating layer outside the first opening may be removed to define the first conductive plug and the second plug. For example, the portions of the first conductive layer and the second layer on the first insulating layer outside the first opening may be planarized to expose the first insulating layer using a chemical mechanical polishing (CMP) process and/or an etching process.

In some embodiments, in forming the first lower electrode, a first conductive layer may be formed on the first conductive plug, on the second plug, and on the first insulating layer. The first conductive layer may be patterned using a mask to define the first lower electrode. Also, prior to patterning the first conductive layer, a continuous phase-changeable material layer may be formed on the first conductive layer, and a second conductive layer may be formed on the phase changeable material layer. The second conductive layer and the continuous phase changeable material layer may also be patterned using the mask to define the phase changeable material layer and the upper electrode.

According to further embodiments of the present invention, a phase changeable memory device may include a substrate and a first insulating layer on the substrate. The first insulating layer may include a first opening extending therethrough. A first conductive plug may be in the first opening on opposing sidewalls thereof and on a surface therebetween, and a second plug may be on the first conductive plug in the first opening. The first conductive plug may be between the second plug and the sidewalls of the first opening, and may be between the second plug and the surface therebetween. A first lower electrode may be on the first conductive plug, on the second plug, and on portions of the first insulating layer outside the first opening therein. In addition, a phase changeable material layer may be on the first lower electrode, and an upper electrode may be on the phase changeable material layer opposite the first lower electrode.

In some embodiments, the device may include a second insulating layer on the first lower electrode. The second insulating layer may have a second opening extending therethrough exposing at least a portion of the first lower electrode. The phase changeable material layer may include a first portion on the second insulating layer, and a second portion extending through the second opening to electrically contact the exposed portion of the first lower electrode.

In other embodiments, the device may include a second lower electrode on at least a portion of the first lower electrode. The second lower electrode may electrically connect the first lower electrode and the phase changeable material layer. Also, a second insulating layer may be on the first lower electrode. The second insulating layer may have a second opening extending therethrough, and may include a spacer on opposing sidewalls of the second opening. The second lower electrode may extend through the second opening between portions of the spacer. A surface area of the second lower electrode may be less than that of the first lower electrode and/or the phase changeable material layer.

In some embodiments, the second plug may be a second conductive plug. The second conductive plug may include tungsten, aluminum, titanium, tantalum, titanium nitride, tungsten nitride, aluminum nitride, and/or titanium aluminum nitride.

In other embodiments, the second plug may be a second insulating plug. The second insulating plug may include tetraethylorthosilicate, undoped silicate glass, spin on glass, high density plasma-chemical vapor deposition oxide, silicon nitride, and/or silicon oxynitride.

According to some embodiments of the present invention, a phase changeable semiconductor memory device may include a conductive structure, a lower electrode structure, a phase changeable material pattern and an upper electrode. The conductive structure may include a first conductive plug and a second plug formed at an upper portion of the first conductive plug. The conductive structure may fill a first opening extended through a first insulation layer. The lower electrode structure may be formed on the conductive structure. The lower electrode structure may include at least one lower electrode and an insulation pattern. The phase changeable material pattern may be formed on the lower electrode structure. The upper electrode may be formed on the phase changeable material pattern.

In other embodiments of the present invention, the insulation pattern may include tetraethylorthosilicate, undoped silicate glass, spin on glass, high density plasma-chemical vapor deposition oxide, silicon nitride, and/or silicon oxynitride.

In some embodiments of the present invention, the spacer may include a material that has an etching selectivity relative to that of the insulation pattern.

In other embodiments of the present invention, the second lower electrode may have an area smaller than that of the first lower electrode, and the insulation pattern may be formed on the first lower electrode around the spacer and the second lower electrode.

In some embodiments of the present invention, the phase changeable material pattern may have an area larger than the second lower electrode.

In other embodiments of the present invention, an additional insulation pattern may be formed on the upper electrode.

According to further embodiments of the present invention, a method of manufacturing a phase changeable semiconductor memory device is provided. In the method of manufacturing a phase changeable semiconductor memory device, a first insulation layer having a first opening may be formed on a substrate. A conductive structure may be formed on the first insulation layer. The conductive structure may include a first conductive plug formed on the first insulation layer and a second plug formed at an upper portion of the first conductive plug. A lower electrode structure may be formed on the conductive structure. The lower electrode structure may include at least one lower electrode and an insulation pattern. A phase changeable material layer may be formed on the lower electrode structure. An upper electrode layer may be formed on the phase changeable material pattern.

In other embodiments of the present invention, the lower electrode structure may be formed by forming a first lower electrode on the conductive structure, by forming a second insulation layer having a second opening on the first lower electrode, by forming a spacer on a sidewall of the second opening, and by forming a second lower electrode on the first lower electrode to fill the second opening.

In some embodiments of the present invention, the spacer may be formed by forming a second layer on the first lower electrode, the second insulation layer and the sidewall of the second opening, and by partially etching the second layer.

In other embodiments of the present invention, the upper electrode layer, the phase changeable material layer and the second insulation layer may be sequentially patterned to form the insulation pattern on the first lower electrode, a phase changeable material pattern on the insulation pattern, and an upper electrode on the phase changeable material pattern.

In some embodiments of the present invention, the upper electrode layer, the phase changeable material layer, the second insulation layer and the lower electrode layer may be sequentially patterned to form the lower electrode on the conductive structure, the insulation pattern on the lower electrode, a phase changeable material pattern on the insulation pattern, and an upper electrode on the phase changeable material pattern.

Thus, according to some embodiments of the present invention, a cavity or a void may not be formed in a conductive structure or between the conductive structure and a lower electrode structure, because the conductive structure may include a first conductive plug and a second plug buried in an upper portion of the first conductive plug. Thus, electrical failure of a phase changeable semiconductor memory device having the conductive structure may be reduced and/or prevented.

### BRIEF DESCRIPTION OF THE DRAWINGS

FIG. 1 is a cross sectional view illustrating a conventional phase changeable semiconductor memory device;

FIG. 2 is a cross sectional view illustrating a phase changeable semiconductor memory device in accordance with some embodiments of the present invention;

FIGS. 3 to 12 are cross sectional views illustrating intermediate fabrication steps of manufacturing a phase changeable semiconductor memory device in accordance with some embodiments of the present invention;

FIGS. 13 to 17 are cross sectional views illustrating intermediate fabrication steps of manufacturing a phase changeable semiconductor memory device in accordance with further embodiments of the present invention;

FIG. 18 is a cross sectional view illustrating a phase changeable semiconductor memory device in accordance with still further embodiments of the present invention; and

FIGS. 19 to 27 are cross sectional views illustrating intermediate fabrication steps of manufacturing a phase changeable semiconductor memory device in accordance with still further embodiments of the present invention.

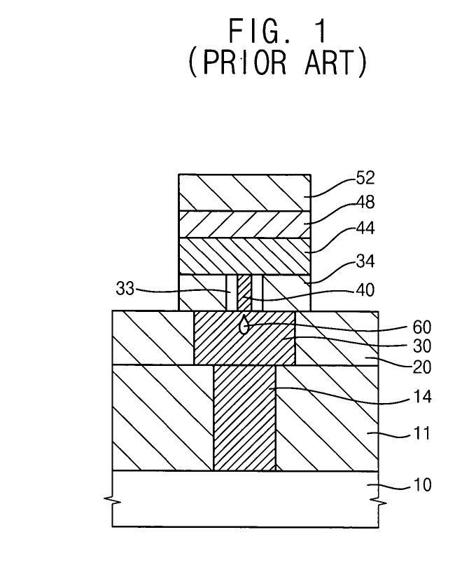

### DETAILED DESCRIPTION OF EMBODIMENTS OF THE INVENTION

The present invention now will be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It will also be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. It will be further understood that terms, such as those defined in commonly used dictionaries, should be interpreted as having a meaning that is consistent with their meaning in the present specification and in the context of the relevant art and will not be interpreted in an idealized or overly formal sense unless expressly so defined herein. All publications, patent applications, patents, and other references mentioned herein are incorporated by reference in their entirety.

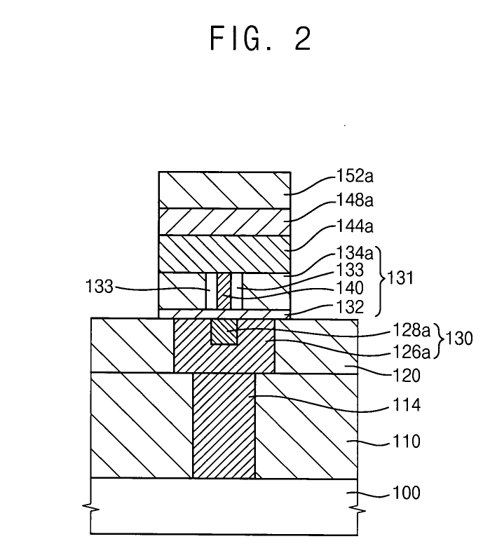

FIG. 2 is a cross sectional view illustrating a phase changeable semiconductor memory device in accordance with some embodiments of the present invention.

Referring now to FIG. 2, the phase changeable semiconductor memory device includes a conductive structure 130, a lower electrode structure 131, a phase changeable material pattern 144a and an upper electrode 148a. The conductive structure 130 includes a first conductive plug/metal pattern 126a and a second plug 128a. The lower electrode structure 131 includes a first lower electrode 132, a second lower electrode 140, an insulation pattern 134a and a spacer 133.

The conductive structure 130 is formed on a semiconductor substrate 100 on which an insulation interlayer 110 is formed. A lower structure (not shown) may be formed between the insulation interlayer 110 and the semiconductor substrate 100. The lower structure may include, for example, a contact region, a transistor, a conductive pattern, and/or a mask pattern.

A pad 114 is formed extending through the insulation interlayer 110. The pad 114 electrically contacts with the contact region of the semiconductor substrate 100. The conductive structure 130 is formed on the pad 114 and the insulation interlayer 110 extending through a first insulation layer 120. In other words, the conductive structure 130 may be buried in (i.e., surrounded by) the first insulation layer 120. That is, a first opening exposing the pad 114 and the insulation interlayer 110 may be formed through the first insulation layer 120, and the conductive structure 130 may be formed on the pad 114 and the insulation interlayer 110 to fill the first opening. The pad 114 may include a conductive material such as metal, conductive metal nitride and/or polysilicon doped with impurities.

The conductive structure 130 is electrically connected to the contact region of the substrate 100 via the pad 114. The conductive structure 130 includes the first conductive plug 126a formed in the first opening on the pad 114 and the insulation interlayer 110, and the second plug 128a formed in the first conductive plug 126a. More particularly, a recess or groove may be formed at a central upper portion of the first conductive plug 126a, for example, where a void or a seam in the first conductive plug 126a may be formed, and the second plug 128a may be formed to fill the recess/groove. Accordingly, the second plug 128a may be “buried” at the central upper portion of the first conductive plug 126a. The first conductive plug 126a may include a metal and/or a conductive metal nitride. For example, the first conductive plug 126a may include tungsten (W), titanium (Ti), tantalum (Ta), aluminum (Al), titanium nitride (TiN), tungsten nitride (WN), aluminum nitride (AlN), and/or titanium aluminum nitride (TiAlN), and/or a combination thereof. The second plug 128a may include a conductive material such as a metal and/or a conductive metal nitride. For example, the second plug 128a may include tungsten, titanium, tantalum, aluminum, titanium nitride, tungsten nitride, aluminum nitride, molybdenum nitride, titanium silicon nitride, and/or titanium aluminum nitride, and/or a combination thereof. Alternatively, the second plug 128a may include an insulation material such as an oxide, an oxynitride, and/or a nitride. For example, the second plug 128a may include tetraethylorthosilicate (TEOS), undoped silicate glass (USG), spin on glass (SOG), high density plasma-chemical vapor deposition (HDP-CVD) oxide, silicon nitride, and/or silicon oxynitride, and/or a combination thereof.

In some embodiments of the present invention, the first conductive plug 126a may include a conductive material substantially similar and/or identical to that of the second plug 128a. In other embodiments of the present invention, the second plug 128a may include a conductive material different than that of first conductive plug 126a. In still other embodiments of the present invention, the first conductive plug 126a may include a conductive material, while the second plug 128a may include an insulation material.

The lower electrode structure 131 includes the first lower electrode 132 formed on the conductive structure 130 and the first insulation layer 120, and the second lower electrode 140 formed on the first lower electrode 132. In addition, the lower electrode structure 131 includes a spacer 133 formed on opposing sidewalls of the second lower electrode 140, and an insulation pattern 134a around the spacer 133 and the second lower electrode 140.

The first lower electrode 132 may have a first surface area and a first thickness. The second lower electrode 140 may have a second surface area smaller than that of the first lower electrode 132, but may have a second thickness thicker than the first thickness. As such, the contact area between the first lower electrode 132 and the second lower electrode 140 may be less than the contact area between the first lower electrode 132 and the conductive structure 130.

In addition, the phase changeable material pattern 144a may have a third surface area that is greater than the second surface area of the second lower electrode 140. As such, the contact area between the second lower electrode 140 and the phase changeable material pattern 144a may be less than the contact area between the phase changeable material pattern 144a and the upper electrode 148a. The third surface area of the phase changeable material pattern 144a may be substantially similar to the first surface area of the first lower electrode 132. Alternatively, the third surface area of the phase changeable material pattern 144a may be greater or less than the first surface area of the first lower electrode 132. A third thickness of the phase changeable material pattern 144a may be substantially similar to the second thickness of the second lower electrode 140. Alternatively, the third thickness of the phase changeable material pattern 144a may be greater or less than or smaller than the second thickness of the second lower electrode 140.

The first lower electrode 132 extends outside the first opening in the first insulation layer 120 and may provide an ohmic contact layer on the first conductive plug 126a and the second plug 128a. In some embodiments of the present invention, the first lower electrode 132 may include a conductive material that includes nitrogen. For example, the first lower electrode 132 may include titanium nitride, tantalum nitride, molybdenum nitride, titanium silicon nitride (TiSiN), titanium aluminum nitride, titanium boron nitride (TiBN), zirconium nitride (ZrN), tungsten silicon nitride (WSiN), tungsten boron nitride (WBN), zirconium aluminum nitride (ZrAlN), molybdenum silicon nitride (MoSiN), molybdenum aluminum nitride (MoAlN), tantalum silicon nitride (TaSiN), titanium aluminum oxynitride (TiAlON), tungsten oxynitride (WON), and/or titanium oxynitride (TiON). In other embodiments of the present invention, the first lower electrode 132 may include a metal such as tungsten, molybdenum, aluminum, titanium, zirconium, tantalum, and/or copper. In still other embodiments of the present invention, the first lower electrode 132 may include a metal silicide such as tungsten silicide, cobalt silicide, titanium silicide, and/or tantalum silicide, and/or a combination thereof.

The second lower electrode 140 may be formed on a central upper portion of the first lower electrode 132. The second lower electrode 140 may include a conductive material including nitrogen (such as a metal nitride), a metal, and/or a metal silicide substantially similar to that of the first lower electrode 132. Alternatively, the second lower electrode 140 may include a conductive material including nitrogen, a metal and/or a metal silicide substantially different from that of the first lower electrode 132.

Still referring to FIG. 2, the second lower electrode 140 is surrounded by an insulation pattern 134a. In other words, an opening partially exposing the first lower electrode 132 is provided through the insulation pattern 134a, and the second lower electrode 140 is formed on the first lower electrode 132 to fill the opening. The insulation pattern 134a may include an oxide, an oxynitride or a nitride. For example, the insulation pattern 134a may include TEOS, USG, SOG, HDP-CVD oxide, silicon nitride, and/or silicon oxynitride.

The spacer 133 is formed between the sidewalls of the second lower electrode 140 and the sidewalls of the opening in the insulation pattern 134a. The spacer 133 may include a material that has an etching selectivity relative to that of the insulation pattern 134a. For example, the spacer 133 may include silicon nitride when the insulation pattern 134a is formed of an oxide. The spacer 133 may reduce the second contact area of the second lower electrode 140. Since the second lower electrode 140 has a second contact area that may be smaller than the first contact area of the first lower electrode 132 and/or the third contact area of the phase changeable material pattern 144a, an interface resistance between the second lower electrode 140 and the first lower electrode 132 may be increased. In addition, an interface resistance between the second lower electrode 140 and the phase changeable material pattern 144a may also be increased. As a result, additional heat may be applied to the phase changeable material pattern 144a, although current flow from the first lower electrode 132 to the phase changeable material pattern 144a and/or from the phase changeable material pattern 144a to the first lower electrode 132 through the second lower electrode 140 may be reduced.

The insulation pattern 134a covers a portion of the first lower electrode 132 and separates the first lower electrode 132 from the phase changeable material pattern 144a. The insulation pattern 134a may also prevent deformation of the phase changeable material pattern 144a.

The phase changeable material pattern 144a is formed on the second lower electrode 140, the insulation pattern 134a and the spacer 133. The phase changeable material pattern 144a may include a chalcogenide. For example, the phase changeable material pattern 144a may include a chalcogenide alloy such as germanium-antimony-tellurium (Ge—Sb—Te; also referred to as GST), arsenic-antimony-tellurium (As—Sb—Te), tin-antimony-tellurium (Sn—Sb—Te), tin-indium-antimony-tellurium (Sn—In—Sb—Te) or arsenic-germanium-antimony-tellurium (As—Ge—Sb—Te). Alternatively, the phase changeable material pattern 144a may include an element in Group Va-antimony-tellurium such as tantalum-antimony-tellurium (Ta—Sb—Te), niobium-antimony-tellurium (Nb—Sb—Te) or vanadium-antimony-tellurium (V—Sb—Te), or an element in Group Va-antimony-selenium such as tantalum-antimony-selenium (Ta—Sb—Se), niobium-antimony-selenium (Nb—Sb—Se) or vanadium-antimony-selenium (V—Sb—Se). Furthermore, the phase changeable material pattern 144a may include an element in Group VIa-antimony-tellurium such as tungsten-antimony-tellurium (W—Sb—Te), molybdenum-antimony-tellurium (Mo—Sb—Te) or chromium-antimony-tellurium (Cr—Sb—Te), or an element in Group VIa-antimony-selenium such as tungsten-antimony-selenium (W—Sb—Se), molybdenum-antimony-selenium (Mo—Sb—Se) or chromium-antimony-selenium (Cr—Sb—Se).

The upper electrode 148a is formed on the phase changeable material pattern 144a. The upper electrode 148a may include a conductive material including nitrogen that is substantially similar to that of the first lower electrode 132 and/or the second lower electrode 140. Alternatively, the upper electrode 148a may include a metal substantially similar to that of the first lower electrode 132 and/or the second lower electrode 140. As a further alternative, the upper electrode 148a may include a material different from that of the first lower electrode 132 and/or the second lower electrode 140.

An additional insulation pattern 152a is formed on the upper electrode 148a. The additional insulation pattern 152a electrically insulates the upper electrode 148a from an upper conductive layer/wiring (not shown).

Since the phase changeable semiconductor memory device illustrated in FIG. 2 includes the conductive structure 130 having the first conductive plug 126a and the second plug 128a, a cavity, seam, and/or void may not be formed between the conductive structure 130 and the lower electrode structure 131. Such a cavity, seam, and/or void may disturb the flow of current between the lower electrode structure 131 and the conductive structure 130. Thus, the likelihood of electrical failure between the conductive structure 130 and the lower electrode structure 131 may be reduced and/or prevented.

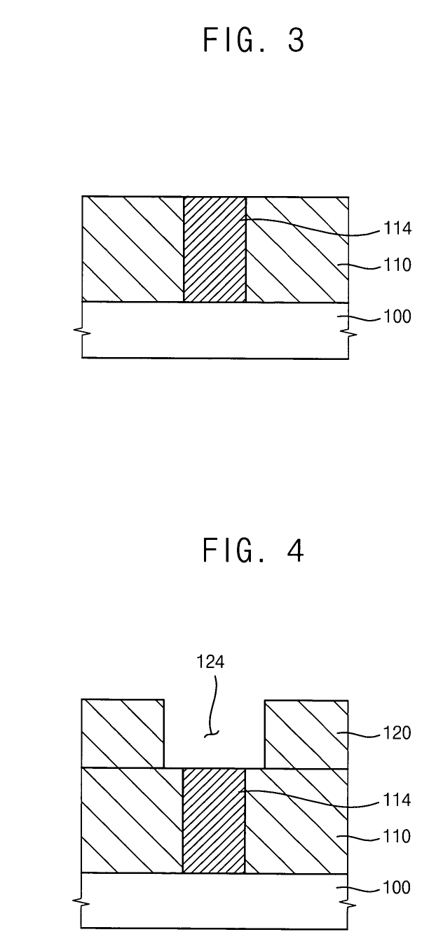

FIGS. 3 to 12 are cross sectional views illustrating exemplary intermediate fabrication steps in a method of manufacturing a phase changeable semiconductor memory device in accordance with some embodiments of the present invention.

Referring now to FIG. 3, an insulation interlayer 110 is formed on a semiconductor substrate 100. A lower structure (not shown) may also be formed on the semiconductor substrate 100. The lower structure may include, for example, a transistor, a contact region, a conductive layer, a mask pattern, and/or a conductive pattern.

The insulation interlayer 110 may be an oxide layer formed by a chemical vapor deposition (CVD) process, a plasma-enhanced chemical vapor deposition (PE-CVD) process, and/or a high density plasma chemical vapor deposition (HDP-CVD) process. For example, the insulation interlayer 110 may be formed using TEOS, BPSG, PSG, USG, SOG, and/or HDP-CVD oxide.

The insulation interlayer 110 is partially etched by a photolithography process, thereby forming a hole extending through the insulation interlayer 110. The hole may expose the lower structure formed on the semiconductor substrate 100. More particularly, the hole may expose the contact region formed at a predetermined portion of the semiconductor substrate 100.

A conductive layer is formed on the insulation interlayer 110 to fill the hole. The conductive layer may be a metal or a conductive metal nitride layer formed by a sputtering process, a CVD process, an atomic layer deposition (ALD) process, and/or a pulse laser deposition (PLD) process. For example, the conductive layer may be formed using tungsten, titanium, aluminum, tantalum, titanium nitride, tungsten nitride, aluminum nitride, and/or titanium aluminum nitride.

The conductive layer is partially removed by a chemical mechanical polishing (CMP) process, an etch back process, or a combination thereof until the insulation interlayer 110 is exposed. Thus, a pad 114 is formed in the hole. The pad 114 is electrically connected to the lower structure. More specifically, the pad 114 may electrically contact the contact region.

Referring to FIG. 4, a first insulation layer 120 is formed on the insulation interlayer 110 and the pad 114. The first insulation layer 120 may be an oxide, a nitride, and/or an oxynitride layer formed by a CVD process, a PECVD process, an HDP-CVD process, and/or an ALD process. For example, the first insulation layer 120 may be formed using USG, TEOS, PSG, BPSG, SOG, HDP-CVD oxide, silicon nitride, and/or silicon oxynitride. The first insulation layer 120 may have a thickness of about 2,000 Å as measured from an upper surface of the insulation interlayer 110. In some embodiments of the present invention, the first insulation layer 120 may be formed using a material substantially similar to that of the insulation interlayer 110. In other embodiments of the present invention, the first insulation layer 120 may be formed using a material that is substantially different from that of the insulation interlayer 110.

The first insulation layer 120 is partially etched to form a first opening 124 that exposes the pad 114. The first opening 124 may have a width substantially wider than that of the pad 114 so that portions of the first insulation interlayer 110 around the pad 114 are also exposed.

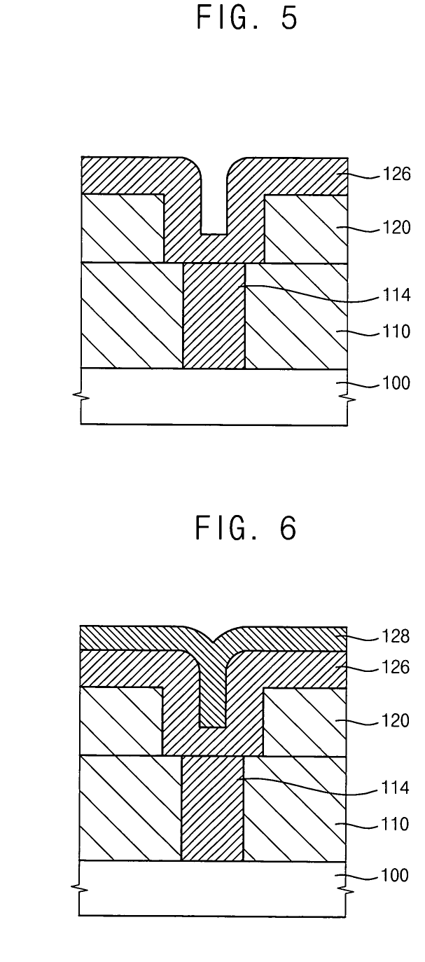

Referring now to FIG. 5, a metal layer 126 is formed on the first insulation layer 120, the pad 114, and on opposing sidewalls and a surface therebetween of the first opening 124 so that the metal layer 126 partially fills the first opening 124. The metal layer 126 may have a thickness of less than about a half of the width of the first opening 124. The metal layer 126 may be formed, for example, of tungsten, aluminum, titanium, tantalum, and/or copper. Additionally, the metal layer 126 may be formed by a sputtering process, a CVD process, an ALD process and/or a PLD process.

According to some embodiments of the present invention, a barrier layer may be formed by a sputtering process, a CVD process, an ALD process or a PLD process before the metal layer 126 is formed. The barrier layer may be formed on the first insulation layer 120, the pad 114 and the sidewall of the first opening 124. The barrier layer may be formed using a conductive metal nitride such as titanium nitride, aluminum nitride, titanium aluminum nitride, tungsten nitride, and/or tantalum nitride.

Referring now to FIG. 6, a first layer 128 is formed on the metal layer 126 to fill the first opening 124. The first layer 128 may be formed of a conductive material such as aluminum, titanium, tungsten, tantalum, aluminum nitride, titanium nitride, tungsten nitride, and/or titanium aluminum nitride. Alternatively, the first layer 128 may be formed of an insulation material such as TEOS, USG, SOG, and/or HDP-CVD oxide. The first layer 128 may be formed on the metal layer 126 by a sputtering process, a CVD process, a PECVD process, an ALD process, and/or a PLD process.

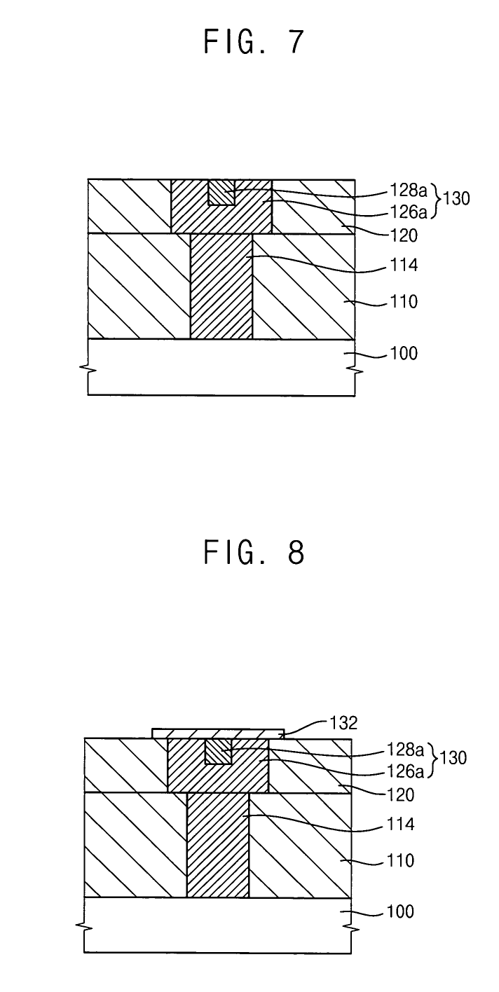

Referring now to FIG. 7, the first layer 128 and the metal layer 126 are partially removed by a CMP process, an etch back process, or a combination thereof until the first insulation layer 120 is exposed, thereby forming a conductive structure 130 that includes a first conductive plug 126a and a second plug 128a. As such, the conductive structure 130 may be buried in (i.e., surrounded by) the first insulation layer 120, and the second plug 128a may be buried in a central upper portion of the first conductive plug 126a.

Referring now to FIG. 8, a first lower electrode layer is formed on the conductive structure 130 and the first insulation layer 120. The first lower electrode layer may be formed of a conductive material including nitrogen (such as a metal nitride), a metal, and/or a metal silicide. For example, the first lower electrode layer may be formed of titanium nitride, tantalum nitride, molybdenum nitride, titanium silicon nitride, titanium aluminum nitride, titanium boron nitride, zirconium nitride, tungsten silicon nitride, tungsten boron nitride, zirconium aluminum nitride, molybdenum silicon nitride, molybdenum aluminum nitride, tantalum silicon nitride, titanium aluminum oxynitride, tungsten oxynitride, titanium oxynitride, tungsten, molybdenum, aluminum, titanium, zirconium, tantalum, copper, tungsten silicide, cobalt silicide, titanium silicide, and/or tantalum silicide. Additionally, the first lower electrode layer may be formed on the conductive structure 130 and the first insulation layer 120 by a sputtering process, a CVD process, an ALD process, and/or a PLD process.

The first lower electrode layer is partially etched to form a first lower electrode 132 on the conductive structure 130 and the first insulation layer 120 extending outside the opening therein. As such, the first lower electrode 132 may have a first surface area that is substantially wider than that of the conductive structure 130. Accordingly, the first lower electrode 132 may extend beyond the conductive structure 130 onto surface portions of the first insulation layer 120.

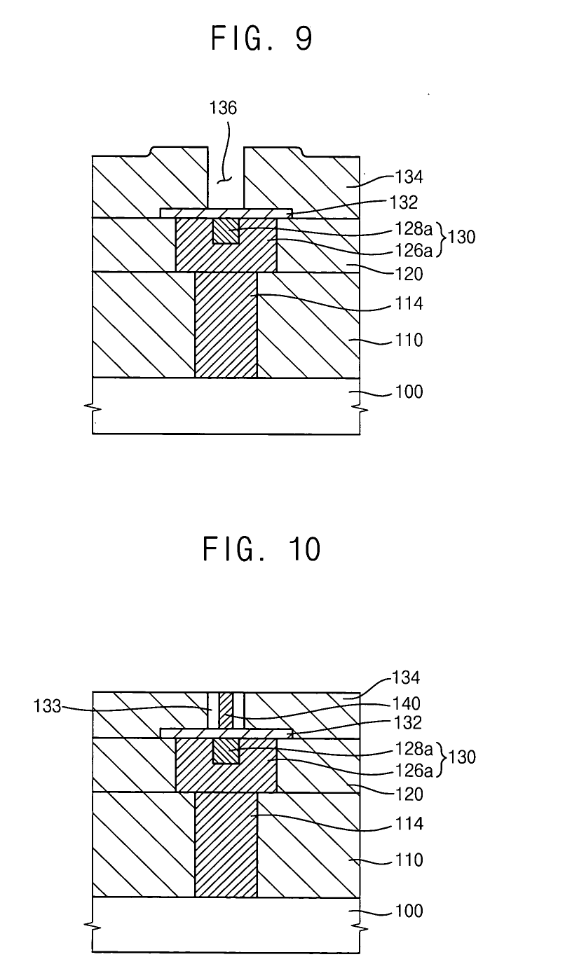

Referring to now FIG. 9, a second insulation layer 134 is formed on the first lower electrode 132 and the first insulation layer 120. The second insulation layer 134 may be an oxide, a nitride and/or an oxynitride layer formed by a CVD process, a PECVD process, an HDP-CVD process and/or an ALD process. For example, the second insulation layer 134 may be formed of USG, TEOS, PSG, BPSG, SOG, HDP-CVD oxide, silicon nitride, and/or silicon oxynitride. In some embodiments of the present invention, the second insulation layer 134 may be formed using a material similar to that of the first insulation layer 120. In other embodiments of the present invention, the second insulation layer 134 may be formed using a material that is substantially different from that of the first insulation layer 120.

The second insulation layer 134 is etched to form a second opening 136 that exposes a portion of the first lower electrode 132. For example, the second insulation layer 134 may be etched by a photolithography process.

Referring now to FIG. 10, a spacer layer is formed on the exposed first lower electrode 132, a sidewall of the second opening 136 and the second insulation layer 134. The spacer layer may be formed using a material that has an etching selectivity with respect to the second insulation layer 134. For example, the spacer layer may be formed using silicon nitride when the second insulation layer 134 is formed using an oxide. Alternatively, when the second insulation layer 134 is formed using a nitride, the spacer layer may be formed using silicon oxide.

The spacer layer and the second insulation layer 134 are partially removed by a CMP process, an etch back process, or a combination thereof so that a spacer 133 is formed on sidewalls of the second opening 136. As such, the second opening 136 is partially filled by the spacer 133. The spacer 133 covers a portion of the exposed first lower electrode 132. More specifically, the area of the first lower electrode 132 that is exposed by the second opening 136 is reduced by twice the width of the spacer 133 when the spacer 133 is formed on the sidewall of the second opening 136.

A second lower electrode layer is formed on the second insulation layer 134 and the spacer 133 to fill the second opening 136. The second lower electrode layer may be formed of a conductive material including nitrogen (such as a metal nitride), a metal, and/or a metal silicide that is similar to that of the first lower electrode layer. Alternatively, the second lower electrode layer may be formed of a conductive material including nitrogen, a metal, and/or a metal silicide that is substantially different from that of the first lower electrode layer. The second lower electrode layer may be formed, for example, by a sputtering process, a CVD process, an ALD process, and/or a PLD process.

The second lower electrode layer is partially removed by a CMP process, an etch back process, or a combination thereof until the second insulation layer 134 is exposed, so that a second lower electrode 140 is formed in the second opening 136. Therefore, a lower electrode structure 131 including the first and second lower electrodes 132 and 140 is formed on the conductive structure 130. The lower electrode structure 131 is electrically connected to the contact region of the semiconductor substrate 100 via the pad 114 and the conductive structure 130. Since the width of the second opening 136 is reduced by the spacer 133, the second lower electrode 140 may have a second surface area that is smaller than the first surface area of the first lower electrode 132, while the second lower electrode 140 may have a second thickness that is thicker than a first thickness of the first lower electrode 132. As such, a smaller contact area between the first lower electrode 132 and the second lower electrode 140 may be provided. However, even though reduced current may flow from the first lower electrode 132 to the second electrode 140 (and vice versa), sufficient heat may be provided via the second lower electrode 140 to change the crystal structure of a phase changeable material.

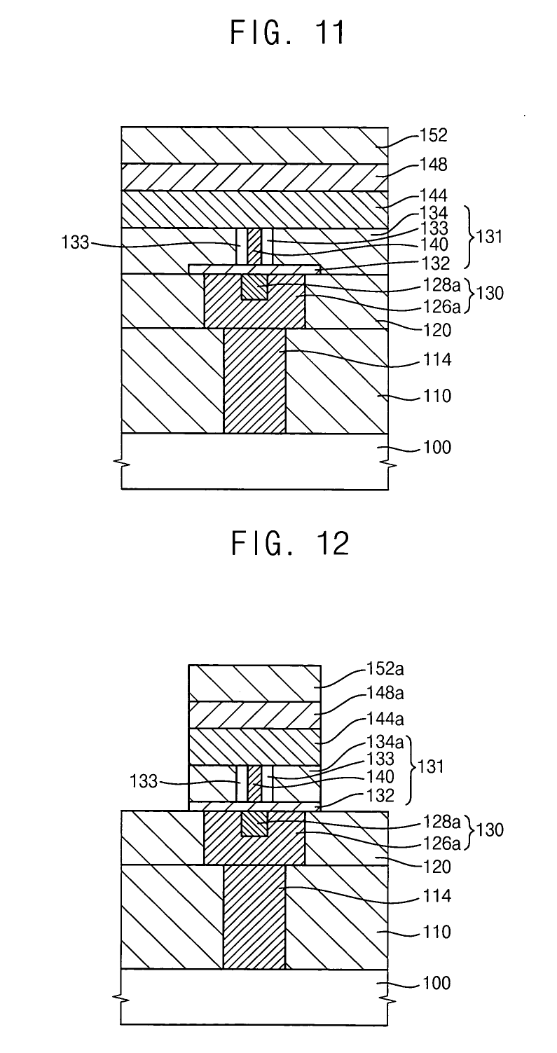

Referring now to FIG. 11, a phase changeable material layer 144 is formed on the second lower electrode 140, the second insulation layer 134 and the spacer 133, for example, by a sputtering process, an ALD process, and/or a CVD process. The phase changeable material layer 144 may be formed using a chalcogenide. For example, the phase changeable material layer may be formed using a chalcogenide alloy such as germanium-antimony-tellurium, arsenic-antimony-tellurium, tin-antimony-tellurium, tin-indium-antimony-tellurium and/or arsenic-germanium-antimony-tellurium. Alternatively, the phase changeable material layer 144 may be formed using an element in Group Va-antimony-tellurium such as tantalum-antimony-tellurium, niobium-antimony-tellurium and/or vanadium-antimony-tellurium, and/or an element in Group Va-antimony-selenium such as tantalum-antimony-selenium, niobium-antimony-selenium and/or vanadium-antimony-selenium. Furthermore, the phase changeable material layer 144 may be formed using an element in Group VIa-antimony-tellurium such as tungsten-antimony-tellurium, molybdenum-antimony-tellurium and/or chromium-antimony-tellurium, and/or an element in Group VIa-antimony-selenium such as tungsten-antimony-selenium, molybdenum-antimony-selenium and/or chromium-antimony-selenium. The phase changeable material layer 144 may have a thickness in the range of about 500 Angstroms (Å) to about 1,000 Å, measured from an upper face of the second lower electrode 140.

Still referring to FIG. 11, an upper electrode layer 148 is formed on the phase changeable material layer 144. The upper electrode layer 148 may be formed of a conductive material including nitrogen similar to that of the first lower electrode 132. Alternatively, the upper electrode layer 148 may be formed using a metal similar to that of the first lower electrode 132. As a further alternative, the upper electrode layer 148 may be formed of a material different that than of the first lower electrode 132. The upper electrode layer 148 may be formed, for example, by a sputtering process, a PLD process, a CVD process, and/or an ALD process.

A third insulation layer 152 is formed on the upper electrode layer 148. The third insulation layer 152 may be formed using a material similar to that of the first insulation layer 120 and/or the second insulation layer 134. Alternatively, the third insulation layer 152 may be formed using a material that is substantially different from that of the first insulation layer 120 and/or the second insulation layer 134. The third insulation layer 152 may be formed, for example, by a CVD process, a PECVD process, an ALD process, and/or an HDP-CVD process.

Referring now to FIG. 12, after a photoresist pattern (not shown) is formed on the third insulation layer 152, the third insulation layer 152, the upper electrode layer 148, the phase changeable material layer 144 and the second insulation layer 134 are patterned. Thus, an insulation pattern 134a, a phase changeable material pattern 144a, an upper electrode 148a and an additional insulation pattern 152a are sequentially formed on the first insulation layer 120. Accordingly, the lower electrode structure 131 including the first lower electrode 132, the second lower electrode 140, the spacer 133 and the insulation pattern 134a is formed on the conductive structure 130 and the first insulation layer 120. The insulation pattern 134a may surround the second lower electrode 140.

The phase changeable material pattern 144a has a third surface area that is greater than the second surface area of the second lower electrode 140. The third surface area of the phase changeable material pattern 144a may be similar in size to the first surface area of the first lower electrode 132. Alternatively, the third surface area of the phase changeable material pattern 144a may be greater than or less than the first surface area of the first lower electrode 132. A third thickness of the phase changeable material pattern 144a may be similar to the second thickness of the second lower electrode 140. Alternatively, the third thickness of the phase changeable material pattern 144a may be greater than or less than the second thickness of the second lower electrode 140.

After an additional insulation interlayer (not shown) is formed on the first insulation layer 120 to cover the additional insulation pattern 152a, an upper wiring/conductive layer (not shown) providing electrical contact with the upper electrode 148a may be formed to complete the phase changeable semiconductor memory device.

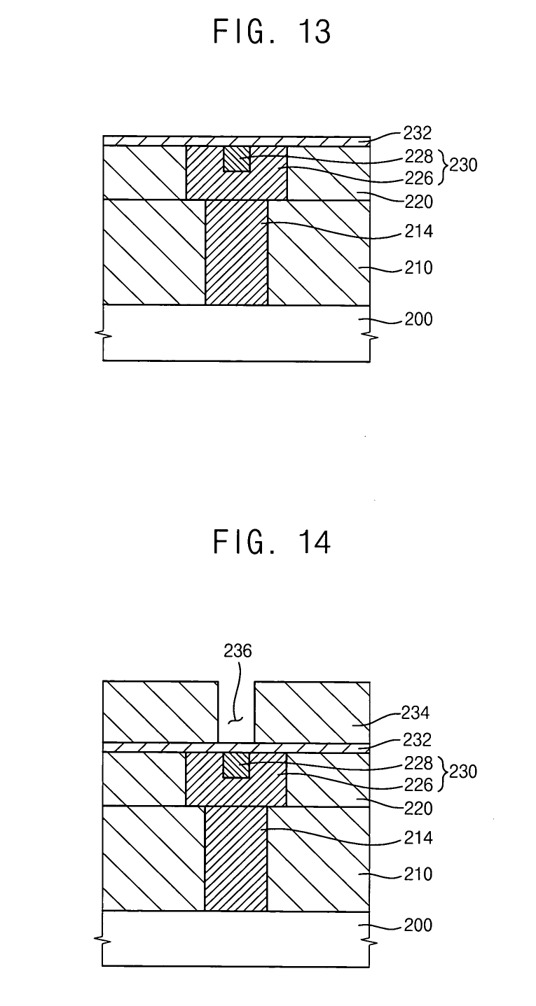

FIGS. 13 to 17 are cross sectional views illustrating intermediate fabrication steps of manufacturing a phase changeable semiconductor memory device in accordance with further embodiments of the present invention.

Referring now to FIG. 13, an insulation interlayer 210 is formed on a semiconductor substrate 200 on which a lower structure may be formed. The lower structure may include, for example, a transistor, a contact region, and/or a conductive pattern.

A pad 214 is formed extending through the insulation interlayer 210. The pad 214 may electrically contact the contact region of the lower structure.

After a first insulation layer 220 is formed on the pad 214 and the insulation interlayer 210, a first opening is formed through the first insulation layer 220. The first opening exposes the pad 214 and a portion of the first insulation layer 220 surrounding the pad 214.

A metal layer is formed on the first insulation layer 220 and in the first opening on sidewalls thereof and on a surface therebetween, and then the metal layer is partially removed until the first insulation layer 220 is exposed. Thus, a first conductive plug 226 is formed on sidewalls of the first opening and on the pad 214. The first conductive plug 226 is electrically connected to the contact region of the substrate 200 via the pad 214.

After a first layer is formed on the first conductive plug 226 and the first insulation layer to completely fill the first opening, the first layer is partially removed, for example, by CMP, to thereby form a second plug 228 in a central upper portion of the first conductive plug 226. As a result, a conductive structure 230 including the first conductive plug 226 and the second plug 228 is formed extending through the first insulation layer 220. The first layer may be formed of a conductive material or an insulation material. As such, the second plug 228 may be formed of a conductive material on an insulation material. For example, the second plug may be formed of a conductive material that is different than that of the first conductive plug 226.

A first lower electrode layer 232 is formed on the conductive structure 230 and the first insulation layer 220 extending outside the opening therein. The first lower electrode layer 232 may have a thickness of about 100 Angstroms (Å) to about 300 Å, as measured from an upper surface of the conductive structure 230. The first lower electrode layer 232 may be formed of a conductive material including nitrogen, a metal, and/or a metal silicide.

Referring now to FIG. 14, a second insulation layer 234 is formed on the first lower electrode layer 232. The second insulation layer 234 is partially etched to form a second opening 236 that exposes a portion of the first lower electrode layer 232 under which the second plug 228 is positioned.

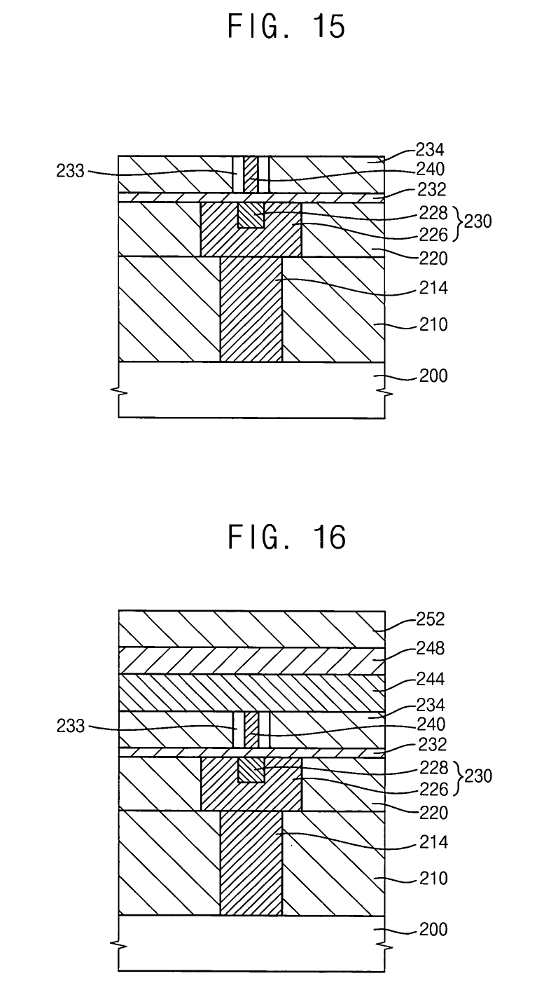

Referring now to FIG. 15, a spacer layer is formed on the second insulation layer 234, on sidewalls of the second opening 236, and on the exposed portion of the first lower electrode layer 232. The spacer layer is partially etched until the second insulation layer 234 is exposed to thereby form a spacer 233 on the sidewalls of the second opening 236. For example, the spacer layer may be etched using an anisotropic etching process to form the spacer 233. When the spacer 233 is formed, the portion of the lower electrode layer 232 that is exposed by the second opening 236 may have a reduced area.

A second lower electrode layer is formed on the second insulation layer 234 and the spacer 233 to fill the second opening 236. The second lower electrode layer may be formed of a material similar to or different from that of the first lower electrode layer 232. The second lower electrode layer is partially removed until the second insulation layer 234 is exposed, thereby forming a second lower electrode 240 in the second opening 236.

Referring now to FIG. 16, a continuous phase changeable material layer 244 is formed on the second lower electrode 240, the second insulation layer 234 and the spacer 233. The phase changeable material layer 244 may be formed using a chalcogenide.

An upper electrode layer 248 is formed on the phase changeable material layer 244, and a third insulation layer 252 is formed on the upper electrode layer 248. The upper electrode layer 248 may be formed of a material similar to or different from that of the first lower electrode layer 232 and/or the second lower electrode layer. Additionally, the third insulation layer 252 may be formed of a material similar to or different from that of the first insulation layer 220 and/or the second insulation layer 234.

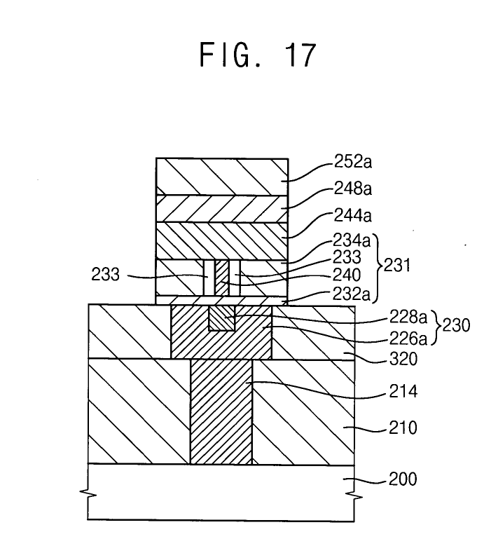

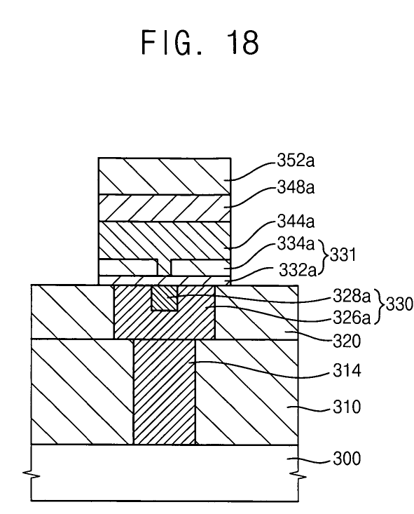

Referring now to FIG. 17, after a photoresist pattern (not shown) is formed on the third insulation layer 252, the third insulation layer 252, the upper electrode layer 248, the phase changeable material layer 244, the second insulation layer 234 and the first lower electrode layer 232 are patterned using the photoresist pattern as an etching mask. Thus, a first lower electrode 232a, an insulation pattern 234a, the phase changeable material pattern 244a, an upper electrode 248a and an additional insulation pattern 252a are sequentially formed on the conductive structure 230 and the first insulation layer 220. As a result, a lower electrode structure 231 including a first lower electrode 232a, a second lower electrode 240, the spacer 233 and the insulation pattern 234a is formed on the conductive structure 230. The second lower electrode 240 may be buried in (i.e., surrounded by) the insulation pattern 234a and may extend therethrough.

FIG. 18 is a cross sectional view illustrating a phase changeable semiconductor memory device in accordance with still further embodiments of the present invention.

Referring now to FIG. 18, the phase changeable semiconductor memory device includes a conductive structure 330, a lower electrode structure 331, a phase changeable material pattern 344a, and an upper electrode 348a. The conductive structure 330 includes a first conductive plug 326a and a second plug 328a. The lower electrode structure 331 includes a lower electrode 332a and an insulation pattern 334a.

The conductive structure 330 is formed on a semiconductor substrate 300 on which an insulation interlayer 310 is formed. A lower structure (not shown) may be formed between the semiconductor substrate 300 and the insulation interlayer 310. The lower structure may include, for example, a contact region, a transistor, a conductive pattern, and/or a mask pattern.

A pad 314 is formed extending through the insulation interlayer 310. The pad 314 electrically contacts the contact region formed on the semiconductor substrate 300. The conductive structure 330 is formed on the pad 314 and the insulation interlayer 310 extending through a first insulation layer 320. In other words, the conductive structure 330 may be buried in (i.e., surrounded by) the first insulation layer 320. More particularly, a first opening exposing the pad 314 and the insulation interlayer 310 is formed through the first insulation layer 320. The conductive structure 330 is then formed on the pad 314 and the insulation interlayer 310 to fill the first opening. The pad 314 may include a conductive material such as metal, conductive metal nitride and/or polysilicon doped with impurities.

The conductive structure 330 is electrically connected to the contact region via the pad 314. The conductive structure 330 includes the first conductive plug 326a formed in the first opening on the pad 314 and the insulation interlayer 310, and the second plug 328a formed on the first conductive plug 326a. More specifically, a recess or groove may be formed in a central upper portion of the first conductive plug 326a, and the second plug 328a may be formed to fill the recess/groove. Thus, the second plug 328a may be “buried” at the central upper portion of the first conductive plug 326a. The first conductive plug 326a may include a metal and/or a conductive metal nitride. For example, the first conductive plug 326a may include tungsten, titanium, tantalum, aluminum, titanium nitride, tungsten nitride, molybdenum nitride, aluminum nitride, and/or titanium aluminum nitride. The second plug 328a may include a conductive material such as a metal and/or a conductive metal nitride. For example, the second plug 328a may include tungsten, titanium, tantalum, aluminum, titanium nitride, tungsten nitride, aluminum nitride, molybdenum nitride, titanium silicon nitride, and/or titanium aluminum nitride. Alternatively, the second plug 328a may include an insulation material such as an oxide, an oxynitride and/or a nitride. For example, the second plug 328a may include TEOS, USG, SOG, HDP-CVD oxide, silicon nitride, and/or silicon oxynitride.

As described above, the first conductive plug 326a may include a conductive material substantially similar to that of the second plug 328a. Alternatively, the second plug 328a may include a conductive material different than that of first conductive plug 326a. Furthermore, the first conductive plug 326a may include a conductive material, while the second plug 328a may include the insulation material.

The lower electrode structure 331 includes the lower electrode 332a formed on the conductive structure 330 and the first insulation layer 320 extending outside the opening therein, and the insulation pattern 334a formed on the lower electrode 332a.

The lower electrode 332a has a first surface area and a first thickness, and the insulation pattern 334a has a second opening exposing a portion of the lower electrode 332a. The lower electrode 332a may serve as an ohmic contact layer on the first conductive plug 326a and the second plug 328a. In some embodiments of the present invention, the lower electrode 332a may include a conductive material including nitrogen. For example, the lower electrode 332a may include titanium nitride, tantalum nitride, molybdenum nitride, titanium silicon nitride, titanium aluminum nitride, titanium boron nitride, zirconium nitride, tungsten silicon nitride, tungsten boron nitride, zirconium aluminum nitride, molybdenum silicon nitride, molybdenum aluminum nitride, tantalum silicon nitride, titanium aluminum oxynitride, tungsten oxynitride, and/or titanium oxynitride. In other embodiments of the present invention, the lower electrode 332a may include a metal such as tungsten, molybdenum, aluminum, titanium, zirconium, tantalum, and/or copper. In still other embodiments of the present invention, the lower electrode 332a may include a metal silicide such as tungsten silicide, cobalt silicide, titanium silicide, and/or tantalum silicide. The insulation pattern 334a may include an oxide, an oxynitride and/or a nitride. For example, the insulation pattern 334a may include TEOS, USG, SOG, HDP-CVD oxide, silicon nitride, and/or silicon oxynitride.

The phase changeable material pattern 344a is formed on the exposed portion of the lower electrode 332a and the insulation pattern 334a. As such, the phase changeable material pattern 344a includes a lower portion that fills the second opening formed through the insulation pattern 334a. That is, the phase changeable material pattern 344a has a lower portion that extends through the second opening in the insulation pattern 334a to electrically connect to the lower electrode 332a. Thus, the phase changeable material pattern 344a may have a “T”-shaped cross section.

The lower portion of the phase changeable material pattern 344a may have a second surface area that is smaller than that of the lower electrode 332a, and a second thickness that is greater than the first thickness of the lower electrode 332a. An upper portion of the phase changeable material pattern 344a has a third surface area that is larger than the second surface area. The third surface area of the phase changeable material pattern 344a may be similar in size to the first surface area of the lower electrode 332a. Alternatively, the upper portion of the phase changeable material pattern 344a may have the third surface area that is greater than or less than the first surface area of the lower electrode 332a. Since the lower portion of the phase changeable material pattern 344a has the second surface area which may be smaller than the first surface area of the lower electrode 332a and/or the third surface area of the upper portion of the phase changeable material pattern 344a, an interface resistance between the lower electrode 332a and the lower portion of the phase changeable material pattern 344a may be increased. As a result, sufficient heat may be applied to the phase changeable material pattern 344a to alter its crystal structure, even though a reduced current may flow from the first electrode 332a to the phase changeable material pattern 344a (and vice versa).

The phase changeable material pattern 344a may include a chalcogenide. For example, the phase changeable material pattern 344a may include a chalcogenide alloy such as germanium-antimony-tellurium, arsenic-antimony-tellurium, tin-antimony-tellurium, tin-indium-antimony-tellurium and/or arsenic-germanium-antimony-tellurium. Alternatively, the phase changeable pattern 344a may include an element in Group Va-antimony-tellurium such as tantalum-antimony-tellurium, niobium-antimony-tellurium and/or vanadium-antimony-tellurium, and/or an element in Group Va-antimony-selenium such as tantalum-antimony-selenium, niobium-antimony-selenium and/or vanadium-antimony-selenium. Furthermore, the phase changeable pattern 144a may include an element in Group VIa-antimony-tellurium such as tungsten-antimony-tellurium, molybdenum-antimony-tellurium and/or chromium-antimony-tellurium, and/or an element in Group VIa-antimony-selenium such as tungsten-antimony-selenium, molybdenum-antimony-selenium and/or chromium-antimony-selenium.

The upper electrode 348a is formed on the phase changeable material pattern 344a. The upper electrode 348a may include a conductive material including nitrogen similar to that of the lower electrode 332a. Alternatively, the upper electrode 348a may include a metal similar to that of the lower electrode 332a.

As a further alternative, the upper electrode 348a may include a material different from that of the lower electrode 332a. An additional insulation pattern 352a is formed on the upper electrode 348a.

The additional insulation pattern 352a electrically insulates the upper electrode 348a from an upper conductive layer and/or wiring (not shown).

Since the phase changeable semiconductor memory device illustrated in FIG. 18 includes the conductive structure 330 having the first conductive plug 326a and the second plug 328a, a cavity, seam, or void may not be formed between the conductive structure 330 and the lower electrode structure 331. Such a cavity/seam/void may disturb the flow of current between the lower electrode structure 331 and the conductive structure 330. Thus, the likelihood of electrical failure between the conductive structure 330 and the lower electrode structure 331 may be reduced and/or prevented.

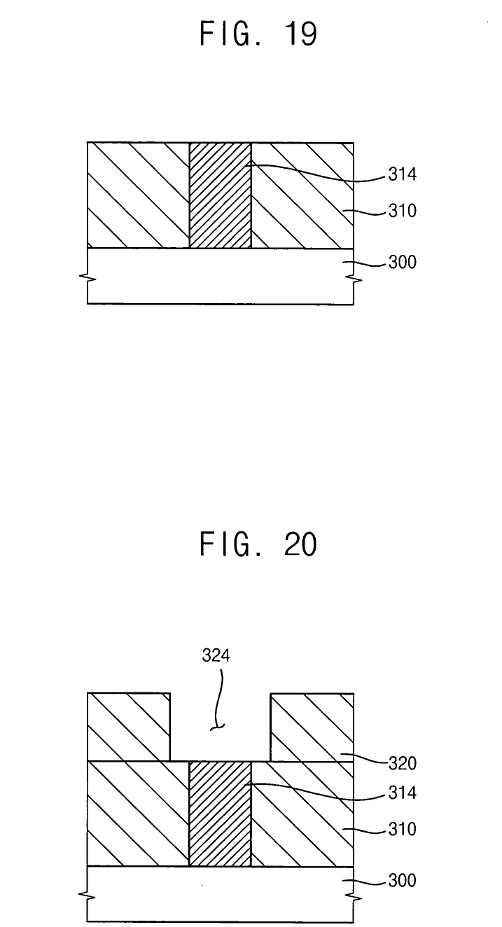

FIGS. 19 to 27 are cross sectional views illustrating intermediate fabrication steps for manufacturing a phase changeable semiconductor memory device in accordance with still further embodiments of the present invention.

Referring now to FIG. 19, an insulation interlayer 310 is formed on a semiconductor substrate 300. A lower structure (not shown) may be formed on the semiconductor substrate 300. The lower structure may include, for example, a transistor, a contact region, a conductive layer, a mask pattern, and/or a conductive pattern.

The insulation interlayer 310 may be an oxide layer formed by a CVD process, a PE-CVD process, and/or an HDP-CVD process. For example, the insulation interlayer 310 may be formed using TEOS, BPSG, PSG, USG, SOG, and/or HDP-CVD oxide.

The insulation interlayer 310 is partially etched to form a hole extending through the insulation interlayer 310. The hole may expose the lower structure formed on the semiconductor substrate 300. In particular, the hole may expose the contact region formed at a portion of the semiconductor substrate 300.

A conductive layer is formed on the insulation interlayer 310 to fill the hole. The conductive layer may be a metal and/or a conductive metal nitride layer formed by a sputtering process, a CVD process, an ALD process and/or a pulse laser deposition (PLD) process. For example, the conductive layer may be formed using tungsten, titanium, aluminum, tantalum, titanium nitride, tungsten nitride, aluminum nitride, and/or titanium aluminum nitride.

The conductive layer is partially removed by a CMP process, an etch back process, or a combination thereof until the insulation interlayer 310 is exposed. Hence, a pad 314 electrically contacting the contact region is formed in the hole.

Referring now to FIG. 20, a first insulation layer 320 is formed on the insulation interlayer 310 and the pad 314. The first insulation layer 320 may be an oxide, a nitride and/or an oxynitride layer formed by a CVD process, a PECVD process, an HDP-CVD process and/or an ALD process. For example, the first insulation layer 320 may be formed using USG, TEOS, PSG, BPSG, SOG, HDP-CVD oxide, silicon nitride, and/or silicon oxynitride. The first insulation layer 320 may have a thickness of about 2,000 Å measured from an upper surface of the insulation interlayer 310. In some embodiments of the present invention, the first insulation layer 320 may be formed using a material substantially similar to that of the insulation interlayer 310. In other embodiments of the present invention, the first insulation layer 320 may be formed using a material substantially different from that of the insulation interlayer 310.

The first insulation layer 320 is partially etched to form a first opening 324 that exposes the pad 314. The first opening 324 may have a width substantially wider than that of the pad 314, so that portions of the first insulation layer 320 surrounding the pad 314 are also exposed.

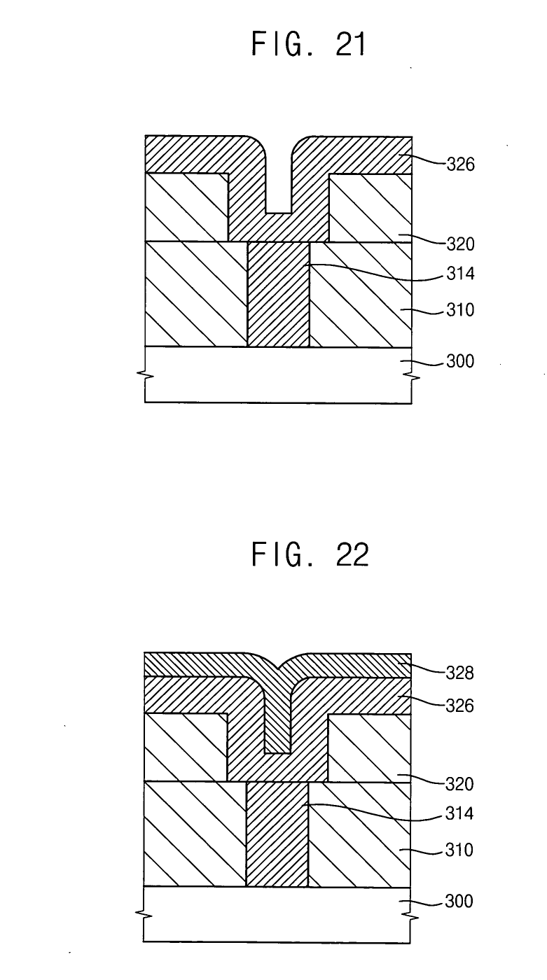

Referring now to FIG. 21, a metal layer 326 is formed on the first insulation layer 320, the pad 314 and on opposing sidewalls of the first opening 324 and on a surface therebetween so that the metal layer 326 partially fills the first opening 324. The metal layer 326 may have a thickness of less than about a half of the width of the first opening 324. The metal layer 326 may be formed using tungsten, aluminum, titanium, tantalum, and/or copper. In addition, the metal layer 326 may be formed by a sputtering process, a CVD process, an ALD process and/or a PLD process.

According to some embodiments of the present invention, a barrier layer (not shown) may be formed by a sputtering process, a CVD process, an ALD process and/or a PLD process before the metal layer 326 is formed. That is, the barrier layer may be formed on the first insulation layer 320, the pad 314 and the sidewalls of the first opening 324. The barrier layer may be formed using a conductive metal nitride such as titanium nitride, aluminum nitride, titanium aluminum nitride, tungsten nitride, and/or tantalum nitride.

Referring now to FIG. 22, a first layer 328 is formed on the metal layer 326 to fill the first opening 324. The first layer 328 may be formed using a conductive material such as aluminum, titanium, tungsten, tantalum, aluminum nitride, titanium nitride, tungsten nitride, and/or titanium aluminum nitride. Alternatively, the first layer 328 may be formed using an insulation material such as TEOS, USG, SOG, and/or HDP-CVD oxide. The first layer 328 may be formed on the metal layer 126 by a sputtering process, a CVD process, a PECVD process, an ALD process, and/or a PLD process.

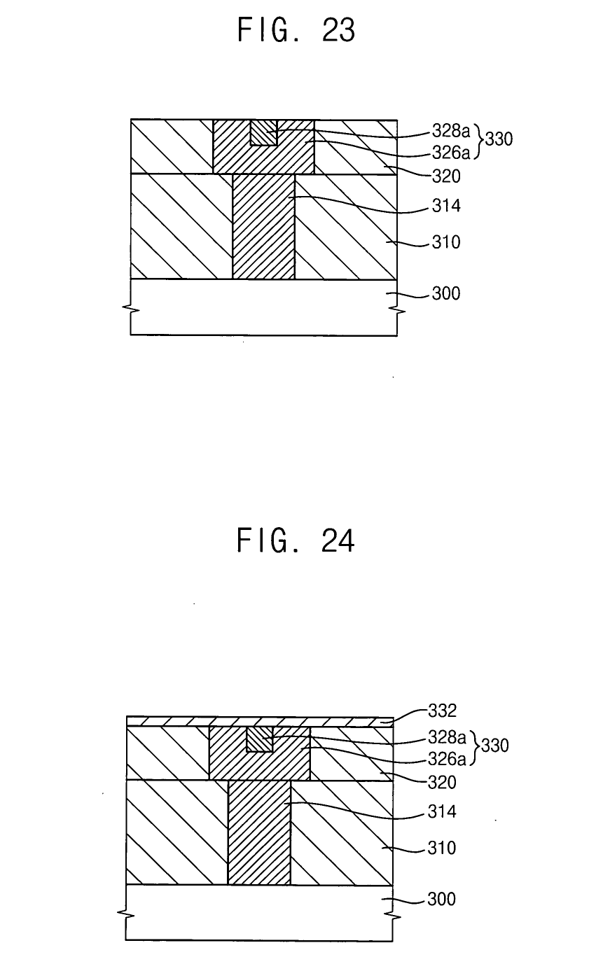

Referring now to FIG. 23, the first layer 328 and the metal layer 326 are partially removed by a CMP process, an etch back process, or a combination thereof until the first insulation layer 320 is exposed, thereby forming a conductive structure 330 extending through the first insulation layer 320 and including a first conductive plug 326a and a second plug 328a. The conductive structure 330 may be buried in (i.e., surrounded by) the first insulation layer 320. The second plug 328a may also be buried in a central upper portion of the first conductive plug 326a.

Referring now to FIG. 24, a lower electrode layer 332 is formed on the conductive structure 330 and the first insulation layer 320 extending outside the opening therein. The lower electrode layer 332 may have a thickness in the range of about 100 Å to about 200 Å as measured from an upper surface of the first insulation layer 320. The lower electrode layer 332 may be formed using a conductive material including nitrogen, a metal and/or a metal silicide. For example, the first lower electrode layer may be formed using titanium nitride, tantalum nitride, molybdenum nitride, titanium silicon nitride, titanium aluminum nitride, titanium boron nitride, zirconium nitride, tungsten silicon nitride, tungsten boron nitride, zirconium aluminum nitride, molybdenum silicon nitride, molybdenum aluminum nitride, tantalum silicon nitride, titanium aluminum oxynitride, tungsten oxynitride, titanium oxynitride, tungsten, molybdenum, aluminum, titanium, zirconium, tantalum, copper, tungsten silicide, cobalt silicide, titanium silicide, and/or tantalum silicide. Additionally, the lower electrode layer 332 may be formed on the conductive structure 330 and the first insulation layer 320 by a sputtering process, a CVD process, an ALD process, and/or a PLD process.

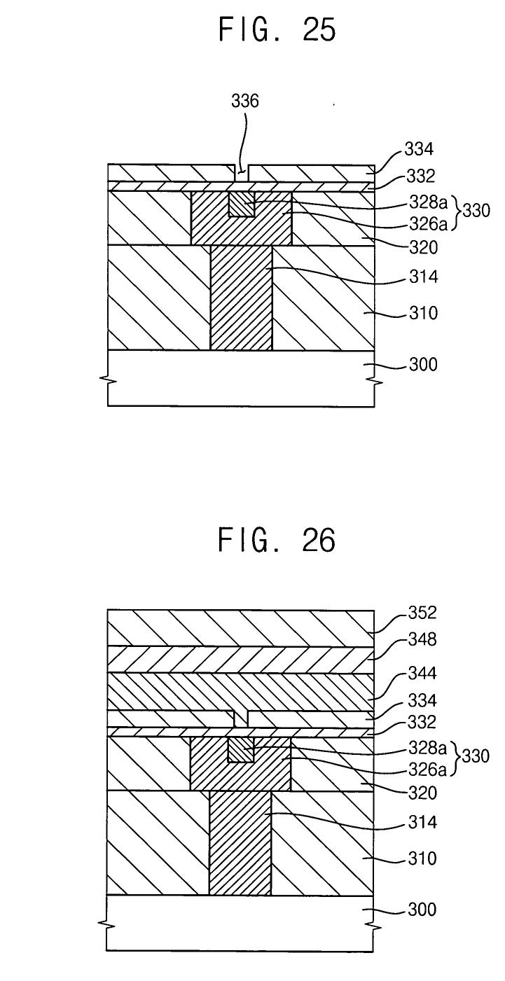

Referring now to FIG. 25, a second insulation layer 334 is formed on the lower electrode layer 332. The second insulation layer 334 may be an oxide, a nitride and/or an oxynitride layer formed by a CVD process, a PECVD process, an HDP-CVD process and/or an ALD process. For example, the second insulation layer 134 may be formed using USG, TEOS, PSG, BPSG, SOG, HDP-CVD oxide, silicon nitride, and/or silicon oxynitride. In some embodiments of the present invention, the second insulation layer 334 may be formed using a material substantially similar to that of the first insulation layer 320. In other embodiments of the present invention, the second insulation layer 334 may be formed using a material substantially different from that of the first insulation layer 320.

The second insulation layer 334 is partially etched to form a second opening 336 that exposes a portion of the lower electrode layer 332 under which the second plug 328a is positioned. As such, the second insulation layer 334 may be divided and/or separated into first and second portions.

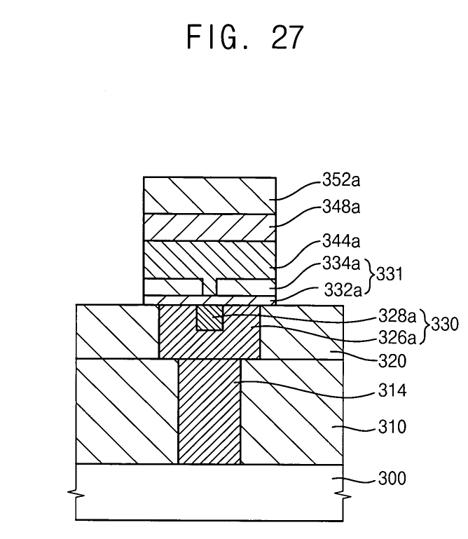

Referring now to FIG. 26, a phase changeable material layer 344 is formed on the second insulation layer 334 to fill the second opening 336. As such, the phase changeable material layer 344 is formed on the exposed portion of the lower electrode layer 332. The phase changeable material layer 344 may be formed by a sputtering process, an ALD process and/or a CVD process. The phase changeable material layer 344 may be formed using a chalcogenide. For example, the phase changeable material layer may be formed using a chalcogenide alloy such as germanium-antimony-tellurium, arsenic-antimony-tellurium, tin-antimony-tellurium, tin-indium-antimony-tellurium and/or arsenic-germanium-antimony-tellurium. Alternatively, the phase changeable material layer 344 may be formed using an element in Group Va-antimony-tellurium such as tantalum-antimony-tellurium, niobium-antimony-tellurium and/or vanadium-antimony-tellurium, and/or an element in Group Va-antimony-selenium such as tantalum-antimony-selenium, niobium-antimony-selenium and/or vanadium-antimony-selenium. Furthermore, the phase changeable material layer 344 may be formed using an element in Group VIa-antimony-tellurium such as tungsten-antimony-tellurium, molybdenum-antimony-tellurium and/or chrome-antimony-tellurium, and/or an element in Group VIa-antimony-selenium such as tungsten-antimony-selenium, molybdenum-antimony-selenium and/or chrome-antimony-selenium. The phase changeable material layer 344 may have a thickness in the range of about 500 Å to about 1,000 Å as measured from an upper surface of the second insulation layer 334.

An upper electrode layer 348 is formed on the phase changeable material layer 344. The upper electrode 348 may be formed using a conductive material including nitrogen substantially similar to that of the lower electrode layer 332. Alternatively, the upper electrode layer 348 may be formed using a metal substantially similar to that of the lower electrode 332. As a further alternative, the upper electrode layer 348 may be formed of a material different from that of the lower electrode layer 332. The upper electrode layer 348 may be formed by a sputtering process, a PLD process, a CVD process, and/or an ALD process.

A third insulation layer 352 is formed on the upper electrode layer 348. The third insulation layer 352 may be formed using a material substantially similar to that of the first insulation layer 320 and/or the second insulation layer 334. Alternatively, the third insulation layer 352 may be formed using a material substantially different from that of the first insulation layer 320 and/or the second insulation layer 334. The third insulation layer 352 may be formed by a CVD process, a PECVD process, an ALD process, and/or an HDP-CVD process.

Referring now to FIG. 27, after a photoresist pattern (not shown) is formed on the third insulation layer 352, the third insulation layer 352, the upper electrode layer 348, the phase changeable material layer 344, the second insulation layer 334 and the lower electrode layer 332 are partially etched. Thus, a lower electrode 332a, an insulation pattern 334a, a phase changeable material pattern 344a, an upper electrode 348a and an additional insulation pattern 352a are sequentially formed on the first insulation layer 320 and the conductive structure 330. As a result, a lower electrode structure 331 including the lower electrode 332a and the insulation pattern 334a is formed on the first insulation layer 320 and the conductive structure 330.

The phase changeable material pattern 344a includes a lower portion that electrically contacts the lower electrode 332a through the second opening 336 of the insulation pattern 334a. The lower portion of the phase changeable material pattern 344a may have a second surface area smaller than the first surface area of the lower electrode 332a. However, an upper portion of the phase changeable material pattern 344a may have a third surface area that is greater than the second surface area of the lower portion thereof. The third surface area of the upper portion of the phase changeable material pattern 344a may be substantially similar to or larger than the first surface area of the lower electrode 332a.

After an additional insulation interlayer (not shown) is formed on the first insulation layer 320 to cover the additional insulation pattern 352a, an upper wiring/conductive layer (not shown) electrically contacting the upper electrode 348a is formed, thereby completing the phase changeable semiconductor memory device.

Thus, according to embodiments of the present invention, a cavity or void may not be formed in a conductive structure and/or between the conductive structure and a lower electrode structure because the conductive structure includes a first conductive plug and a second plug buried in an upper portion of the first conductive plug. Thus, electrical failure of a phase changeable semiconductor memory device having such a conductive structure may be reduced and/or prevented, thereby improving electrical characteristics of the phase changeable semiconductor memory device.

While the present invention has been particularly shown and described with reference to exemplary embodiments thereof, it will be understood by those of ordinary skill in the art that various changes in form and details may be made therein without departing from the spirit and scope of the present invention as defined by the following claims and their equivalents.

That which is claimed:

1. A method of fabricating a phase changeable memory device, the method comprising:
forming a first insulating layer having a first opening extending therethrough on a substrate;
forming a first conductive plug in the first opening on opposing sidewalls thereof and on a surface therebetween;
forming a second plug on the first conductive plug in the first opening, wherein the first conductive plug is between the second plug and the sidewalls of the first opening and between the second plug and the surface therebetween;
forming a first lower electrode on the first conductive plug, on the second plug, and on portions of the first insulating layer outside the first opening therein;
forming a phase changeable material layer on the first lower electrode; and
forming an upper electrode on the phase changeable material layer opposite the first lower electrode.

2. The method of claim 1, further comprising:
forming a second insulating layer on the first lower electrode, the second insulating layer having a second opening extending therethrough exposing at least a portion of the first lower electrode,
wherein forming the phase changeable material layer comprises forming the phase changeable material layer on the second insulating layer and extending through the second opening therein to electrically contact the exposed portion of the first lower electrode.

3. The method of claim 1, further comprising:
forming a second lower electrode on at least a portion of the first lower electrode to electrically connect the first lower electrode and the phase changeable material layer.

4. The method of claim 3, wherein forming the second lower electrode comprises:
forming a second insulating layer having a second opening extending therethrough on the first lower electrode;
forming a spacer on opposing sidewalls of the second opening; and
forming the second lower electrode in the second opening adjacent the spacer.

5. The method of claim 3, wherein a surface area of the second lower electrode is less than that of the first lower electrode and/or the phase changeable material layer.

6. The method of claim 3, wherein the first lower electrode and/or the second lower electrode comprise titanium nitride, tantalum nitride, molybdenum nitride, titanium silicon nitride, titanium aluminum nitride, titanium boron nitride, zirconium nitride, tungsten silicon nitride, tungsten boron nitride, zirconium aluminum nitride, molybdenum silicon nitride, molybdenum aluminum nitride, tantalum silicon nitride, titanium aluminum oxynitride, tungsten oxynitride, titanium oxynitride, tungsten, molybdenum, aluminum, titanium, zirconium, tantalum, copper, tungsten silicide, cobalt silicide, titanium silicide, and/or tantalum silicide.

7. The method of claim 1, wherein the first lower electrode and/or the upper electrode comprise a conductive material containing nitrogen, a metal, and/or a metal silicide.

8. The method of claim 1, wherein the second plug is a second conductive plug comprising a different material than the first conductive plug.

9. The method of claim 8, wherein the second conductive plug comprises tungsten, aluminum, titanium, tantalum, titanium nitride, tungsten nitride, aluminum nitride, and/or titanium aluminum nitride.

10. The method of claim 1, wherein the first conductive plug, the second plug, the first lower electrode, and/or the upper electrode comprise a same material.

11. The method of claim 1, wherein the second plug is a second insulating plug.

12. The method of claim 11, wherein the second insulating plug comprises tetraethylorthosilicate, undoped silicate glass, spin on glass, high density plasma-chemical vapor deposition oxide, silicon nitride, and/or silicon oxynitride.

13. The method of claim 12, wherein the second insulating plug and the insulating layer comprise a same material.

14. The method of claim 1, wherein forming the first conductive plug and the second plug comprises:
forming a first conductive layer on the first insulating layer and in the first opening on sidewalls thereof and on a surface therebetween;
forming a second layer on the first conductive layer; and
removing portions of the first conductive layer and the second layer on the first insulating layer outside the first opening therein to define the first conductive plug and the second plug.

15. The method of claim 14, wherein the first conductive layer is formed to a thickness of less than about half of a width of the first opening in the first insulating layer.

16. The method of claim 14, wherein removing portions of the first conductive layer and the second layer comprises:
planarizing the portions of the first conductive layer and the second layer on the first insulating layer outside the first opening to expose the first insulating layer using an etching process and/or a chemical mechanical polishing (CMP) process.

17. The method of claim 1, wherein forming the first lower electrode comprises:
forming a first conductive layer on the first conductive plug, on the second plug, and on the first insulating layer; and
patterning the first conductive layer using a mask to define the first lower electrode.

18. The method of claim 17, wherein forming the phase changeable material layer and forming the upper electrode comprises the following prior to patterning the first conductive layer:
forming a continuous phase-changeable material layer on the first conductive layer;
forming a second conductive layer on the phase changeable material layer; and
patterning the second conductive layer and the continuous phase changeable material layer using the mask to define the phase changeable material layer and the upper electrode.

19. A phase changeable memory device, comprising:
a substrate;
a first insulating layer having a first opening extending therethrough on the substrate;
a first conductive plug in the first opening on opposing sidewalls thereof and on a surface therebetween;
a second plug on the first conductive plug in the first opening, wherein the first conductive plug is between the second plug and the sidewalls of the first opening and between the second plug and the surface therebetween;
a first lower electrode on the first conductive plug, on the second plug, and on portions of the first insulating layer outside the first opening therein;
a phase changeable material layer on the first lower electrode; and
an upper electrode on the phase changeable material layer opposite the first lower electrode.

20. The device of claim 19, further comprising:
a second insulating layer on the first lower electrode, the second insulating layer having a second opening extending therethrough exposing at least a portion of the first lower electrode,
wherein the phase changeable material layer includes a first portion on the second insulating layer and a second portion extending through the second opening to electrically contact the exposed portion of the first lower electrode.

21. The device of claim 19, further comprising:
a second lower electrode on at least a portion of the first lower electrode electrically connecting the first lower electrode and the phase changeable material layer.

22. The device of claim 21, further comprising:
a second insulating layer having a second opening extending therethrough on the first lower electrode; and
a spacer on opposing sidewalls of the second opening,
wherein the second lower electrode extends through the second opening between portions of the spacer.

23. The device of claim 21, wherein a surface area of the second lower electrode is less than that of the first lower electrode and/or the phase changeable material layer.

24. The device of claim 19, wherein the second plug is a second conductive plug comprising tungsten, aluminum, titanium, tantalum, titanium nitride, tungsten nitride, aluminum nitride, and/or titanium aluminum nitride.

25. The device of claim 19, wherein the second plug is a second insulating plug comprising tetraethylorthosilicate, undoped silicate glass, spin on glass, high density plasma-chemical vapor deposition oxide, silicon nitride, and/or silicon oxynitride.
